(19) United States
(12) Patent Application Publication
(10) Pub. No.: US 2025/0079252 A1
(43) Pub. Date: Mar. 6, 2025

(54) INSULATION SHEET FOR CHIP ON FILM, INSULATION CHIP ON FILM PACKAGE COMPRISING SAME, AND DISPLAY DEVICE

(71) Applicant: AMOGREENTECH CO., LTD., Gimpo-si (KR)

(72) Inventors: In Yong SEO, Gimpo-si (KR); Dae Woo SON, Gimpo-si (KR); Jae Hyung SEO, Gimpo-si (KR); Jong Eun KIM, Gimpo-si (KR); Jong Soo KIM, Gimpo-si (KR)

(21) Appl. No.: 18/246,841

(22) PCT Filed: Sep. 28, 2021
(86) PCT No.: PCT/KR2021/013239

§ 371 Date: Mar. 27, 2023

(30) Foreign Application Priority Data
Sep. 29, 2020 (KR) 10-2020-0126918
Nov. 19, 2020 (KR) 10-2020-0155597

(51) Int. Cl. H01L 23/367; H01L 23/29; H01L 23/373; H01L 25/16

(52) U.S. Cl. CPC H01L 23/367; H01L 23/293; H01L 23/3737; H01L 25/162

(57) ABSTRACT

Provided is an insulation sheet for a chip on film. An insulation sheet for a chip on film according to one embodiment of the present invention is provided on the opposite surface of a printed circuit film from the surface on which a display driver IC (DDI) is mounted, and is for preventing heat generated from the display driver IC from being transferred in a direction perpendicular to the opposite surface. Accordingly, the insulation sheet for a chip on film is advantageous for lowering the temperature of the display driver IC while minimizing the transfer of received heat toward a display device housing. Moreover, due to the excellent flexibility of the insulation sheet, peeling can be prevented even when the insulation sheet is attached to a printed circuit film that is curved.

### TECHNICAL FIELD

The present invention relates to an insulation sheet, and more specifically, to an insulation sheet for a chip on film.

### BACKGROUND ART

As integration of an integrated circuit (IC) increases caused by industrial advancement, due to the complicated structures and the trend towards slimness, miniaturization, and high-performance of hybrid packages and multi-modules, sealed integrated circuits such as a light emitting diode (LED) or the like, and electronic devices, a heat generation amount in various electronic components tends to increase.

Accordingly, effectively dissipating a lot of heat generated in a narrow space in an electronic device to prevent malfunction of and damage to electronic components has emerged as an important task.

Meanwhile, considering the performance and durability of an electronic device, the heat generated by the electronic device should be dissipated to the outside, but this causes a problem in that a lot of heat is sensed in a housing of the electronic device or around the electronic device.

Specifically, recently, as an electronic device tends to be slim or miniaturized, gaps between various components and a housing in the electronic device is almost disappearing, and further, as the number or types of various components required in a high-performance electronic device increase and thus heat generation becomes worse, a case in which a temperature of or around the housing causes discomfort to a user coming into contact with the electronic device or is mistaken for abnormal operation of the electronic device frequently occurs.

A representative example of this electronic device is a display device. The display devices are still being mass produced as low-cost models, but on the other hand, as a large size and high performance are promoted, a greater number of pixels are designed in a limited region, and in conjunction with this, the number of driver ICs which control individual pixels provided in one display device also tends to increase.

Meanwhile, in order to package a driving chip, packaging technologies such as a tape carrier package (TCP), a chip on glass (COG), a chip on film (COF), and the like have been developed. These methods can be regarded as wireless methods, and from the late 1990s, in order to reduce process costs and improve yield according to fine pitch, the share of the chip on film (COF) technology in the package market has gradually increased.

The chip on film (COF) technology is a new type of package developed to cope with the trend of lightening, thinning, and miniaturization of a communication device in a driving chip. However, chip on film (COF) packaging also has a heat generation problem due to a large number of driving chips required to implement a display device having high resolution. Further, in a trend of slimming for minimizing a gap between a display device housing and a display component, a rise in temperature of the housing due to heat generation of the driving chip can cause discomfort to or burn a user coming into contact with the display device.

### DISCLOSURE

### Technical Problem

The present invention has been devised in view of the above points and is directed to providing an insulation sheet capable of minimizing or preventing the conduction or radiation of heat to an upper portion of the sheet by receiving heat from a heating element to reduce a heating level of the heating element and minimize transfer of the received heat in a vertical direction, and for example, providing an insulation sheet suitable for being applied to a chip on film.

Further, the present invention is directed to providing an insulation sheet having excellent flexibility and thus prevented from peeling even when attached to a curved attachment surface, and for example, providing an insulation sheet suitable for being applied to a chip on film assembled in a state of having a predetermined curvature during assembly of a display device.

### Technical Solution

In order to solve the above-described problem, the present invention provides an insulation sheet for a chip on film (COF) provided on an opposite surface of one surface of a printed circuit film, on which a display driving chip (a display driver IC, (DDI)) is mounted, to block the transfer of heat generated from the display driving chip in a first direction perpendicular to the opposite surface,

the insulation sheet including: an insulation member formed of a graphite sheet including a first surface and a second surface facing each other and having a surface direction perpendicular to a thickness direction, and having functions of receiving heat toward the first surface adjacent to the display driving chip to lower a heating temperature of the display driving chip, and moving the received heat more in the surface direction than in the thickness direction to minimize heat transfer in the first direction from the second surface; a first adhesive member including a metal base material for forming a hot spot larger than an area of the display driving chip and having high temperature reliability, a first adhesive layer attached to the opposite surface of the printed circuit film at a position corresponding to the display driving chip, and a second adhesive layer attached to the first surface of the insulation member; and a protective member provided on the second surface of the insulation member.

According to one embodiment of the present invention, a length and a width of each of the protective member and the first adhesive member may be formed to be greater than a length and a width of the insulation member so that four side surfaces of the insulation member may be sealed through the protective member and the first adhesive member.

Further, a length and a width of each of the protective member and the first adhesive member may be formed to be greater than a length and a width of the insulation member so that four side surfaces parallel to the thickness direction of the insulation member may be sealed through the protective member and the first adhesive member.

In addition, the graphite sheet may include one or more sheets of an artificial graphite sheet and a multilayer graphene sheet.

In addition, a thickness of the graphite sheet may be 15 to 100 μm.

In addition, the metal base material may include one or more of a copper foil and an aluminum foil.

In addition, a thickness of the metal base material may be 7 to 75 μm, and thicknesses of the first adhesive layer and the second adhesive layer may each be independently 7 to 55 μm.

In addition, a length and a width of the metal base material may be provided to be greater than a length and a width of the display driving chip, and smaller than a length and a width of the graphite sheet.

In addition, a release film may be further provided on the first adhesive layer of the first adhesive member.

In addition, the insulation sheet may further include a second adhesive member between the protective member and the insulation member, and the second adhesive member may include a third adhesive layer attached to the protective member, a fourth adhesive layer attached to the insulation member, and a metal base material interposed between the third adhesive layer and the fourth adhesive layer.

In addition, a length and a width of each of the protective member, the first adhesive member, and the second adhesive member may be formed to be greater than a length and a width of the insulation member so that four side surfaces parallel to the thickness direction of the insulation member may be sealed through the protective member, the first adhesive member, and the second adhesive member.

In addition, the present invention provides an insulation chip on film (COF) package including: a printed circuit film; a display driving chip (DDI) disposed on one surface of the printed circuit film; and the insulation sheet for a chip on film (COF) according to the present invention disposed on an opposite surface of the printed circuit film at a position corresponding to the display driving chip.

According to one embodiment of the present invention, an area of the insulation sheet for a chip on film (COF) may be provided to be three to five times larger than an area of the display driving chip.

Further, the present invention provides a display module including: a display panel unit; a circuit board disposed to be spaced apart from the display panel unit; and the insulation chip on film package according to the present invention of which one end is electrically connected to the display panel unit, and the other end is electrically connected to the circuit board.

In addition, the present invention provides a display device including: the display module according to the present invention; and a housing surrounding at least a portion of the display module.

According to one embodiment of the present invention, an insulation chip on film package provided in the display module may be disposed in a space between an inner side surface of the housing and a display panel unit in the display module, an insulation sheet for a chip on film provided in the insulation chip on film package may be disposed to face the inner side surface of the housing, and an air layer may be formed between the insulation sheet and the inner side surface of the housing to prevent heat transfer from an exposed surface of the insulation sheet for a chip on film toward the inner side surface of the housing perpendicular to the exposed surface of the insulation sheet for a chip on film.

Further, the present invention provides an insulation sheet disposed on a hot spot surface to block the transfer of heat generated from a hot spot in any one direction perpendicular to the hot spot surface, the insulation sheet including: an insulation member formed of a graphite sheet including a first surface and a second surface facing each other and having a surface direction perpendicular to a thickness direction, and having functions of receiving heat toward the first surface adjacent to the hot spot to lower a temperature of the hot spot, and moving the received heat more in the surface direction perpendicular to the thickness direction than in the thickness direction from the first surface to the second surface to minimize heat transfer in any one direction perpendicular to the hot spot surface from the second surface; a first adhesive member disposed on the first surface of the insulation member to be attached to the hot spot; and a protective member disposed on the second surface of the insulation member.

In addition, the present invention provides an insulation sheet disposed on a hot spot surface to block the transfer of heat generated from a hot spot in any one direction perpendicular to the hot spot surface, the insulation sheet including: an insulation member including a first surface and a second surface facing each other and having a surface direction perpendicular to a thickness direction, and of which thermal conductivity in the surface direction is at least three times greater than thermal conductivity in the thickness direction for receiving heat toward the first surface adjacent to the hot spot to lower a temperature of the hot spot, and minimizing heat transfer in any one direction perpendicular to the hot spot surface from the second surface; a first adhesive member disposed on the first surface of the insulation member; and a protective member disposed on the second surface of the insulation member. In this case, the insulation member may include a graphite sheet.

According to one embodiment of the present invention, the first adhesive member may be formed of an adhesive layer or provided with adhesive layers on both surfaces of a base material. In this case, the base material may be a polymer film, a metal foil, and a nano fiber web.

Further, the base material may be a metal foil to form a hot spot larger than a hot spot area and have high temperature reliability.

In addition, the protective member may include a nonporous film, a nano fiber web, or a stacked nonporous film on the nano fiber web.

In addition, the present invention provides an insulation structure including: a heating element; and the insulation sheet according to the present invention provided on the heating element.

According to one embodiment of the present invention, an area of the insulation sheet may be provided to be three to five times larger than an area of the heating element.

Hereinafter, terms of the present invention are defined.

A meaning of ‘B provided on A’ or ‘B disposed on A’ used in the present invention includes not only a case in which B is directly provided or disposed on A, but also a case in which another C is interposed between A and B to be provided or disposed.

### Advantageous Effects

An insulation sheet according to the present invention can receive heat from a heating element to reduce a heating level of the heating element and minimize transfer of the received heat in a vertical direction, and thus is advantageous in minimizing or preventing heat transfer in an undesirable direction. Further, since flexibility is excellent, peeling can be prevented even when the insulation sheet is attached to a curved attachment surface. Furthermore, since the insulation sheet according to one embodiment of the present invention can prevent scattering of dust which can occur due to damage to or destruction of a layer in the insulation sheet, a malfunction of or damage to an electronic component due to the dust can be prevented, and more improved adhesive characteristics on the curved attachment surface can be expressed. Accordingly, the insulation sheet according to the present invention is very suitable for blocking the transfer of heat emitted from a display driving chip, which is a heating element provided on a chip on film, to a housing, and in addition, can be widely applied to various electronic components or goods.

### DESCRIPTION OF DRAWINGS

FIGS. 1 to 9 are schematic cross-sectional views of insulation sheets according to various embodiments of the present invention.

FIGS. 10 and 11 are a schematic cross-sectional view and a heat flow diagram of insulation chip on film packages according to various embodiments of the present invention.

FIG. 12 is a schematic cross-sectional view of a display module according to one embodiment of the present invention.

FIG. 13 is a plan view of the display module according to one embodiment of the present invention.

FIGS. 14 and 15 are partial schematic cross-sectional views of display devices according to various embodiments of the present invention.

### MODES OF THE INVENTION

Hereinafter, exemplary embodiments of the present invention will be described in detail with reference to the accompanying drawings which may allow one of ordinary skill in the art to easily carry out the present invention. The present invention may be implemented in various forms and is not limited to the following embodiments. Components not related to the description are not included in the drawings to clearly describe the present invention, and the same reference symbols are used for the same or similar components in the description.

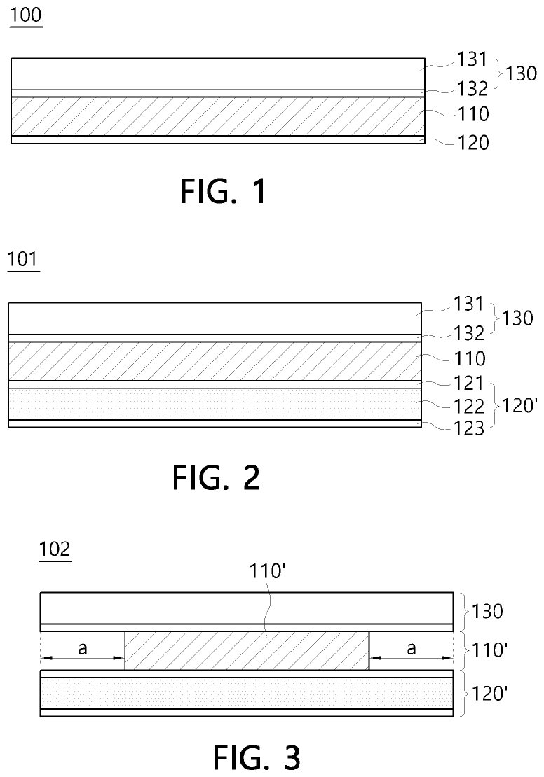

In a description with reference to FIG. 1, an insulation sheet 100 according to one embodiment of the present invention is implemented by including an insulation member 110 including a first surface and a second surface facing each other and having a surface direction perpendicular to a thickness direction, a protective member 130 provided on the second surface of the insulation member, and a first adhesive member 120 provided on the first surface of the insulation member.

In a description of an insulation mechanism of the insulation sheet 100, heat which reached the first surface of the insulation member 110 from a heating element, which is a hot spot, through the first adhesive member 120 is predominantly expressed in the surface direction perpendicular to the thickness direction and more heat moves in the surface direction than the thickness direction until a thermal capacity of the insulation member 110 is saturated by thermal conduction characteristics of the insulation member 110. This thermal conduction tendency may minimize the movement of heat in the thickness direction of the insulation member 110 toward the second surface from the first surface and thus express a heat dissipation effect of lowering the temperature of the heating element, which is a hot spot, while expressing an insulation effect of minimizing or preventing heat transfer in a vertical direction from the second surface of the insulation sheet 100.

For example, in the insulation member 110, the thermal conductivity in the surface direction perpendicular to the thickness direction is three times or more, and preferably four times or more the thermal conductivity in the vertical direction. When the thermal conductivity in the surface direction perpendicular to the thickness direction of the insulation member 110 is smaller than three times the thermal conductivity in the thickness direction, insulation performance may not be sufficiently expressed.

The insulation member 110 may be one insulation layer or a plurality of stacked insulation layers. In this case, when the insulation member 110 is formed of one insulation layer, the thermal conduction characteristics of the insulation member 110 may be thermal conduction characteristics of the insulation layer. However, when the insulation member 110 is in the form of a plurality of stacked insulation layers or includes another layer such as an adhesive layer in addition to the insulation layer, the thermal conduction characteristics of the individual insulation layers do not need to be the same as the thermal conduction characteristics of the above-described insulation member 110, and only need to satisfy the thermal conduction characteristics of the above-described insulation member 110 as a combined whole.

Any member capable of expressing the thermal conduction characteristics of the above-described insulation member may be used as the insulation layer without limitation. For example, the insulation layer may be a graphite sheet, and specifically, may include an artificial graphite sheet and/or a multilayer graphene sheet. Meanwhile, it may be difficult for a natural graphite sheet alone to express a desired function of the insulation member of the present invention. Further, when the insulation layer is a graphite sheet, specifically, an artificial graphite sheet or a multilayer graphene sheet, there is an advantage in that flexibility is very excellent and thus a crack or damage may be minimized or prevented even when the insulation layer is attached to a severely curved attachment surface in addition to expressing desired thermal conductivity.

When a graphite sheet is used as the insulation member, a thickness may be 15 to 100 μm, preferably 15 to 70 μm, and for example 40 μm. When the thickness exceeds 100 μm, the thermal capacity increases, which is advantageous for improving a heat dissipation effect on the heating element and an insulation effect due to the insulation sheet 100, but there is a concern in that the thermal conductivity in the surface direction is lowered and thus may approach the thermal conductivity in the thickness direction. Further, since the flexibility of the graphite sheet is lowered, it may be difficult to apply the graphite sheet to a curved attachment surface. Furthermore, the damage caused when the graphite sheet is applied to the curved attachment surface may reduce the heat dissipation effect and/or the insulation effect. Meanwhile, the caused damage may generate dust, and there is a concern in that electrical short circuits of nearby electric and electronic components are caused due to scattering of the dust. Further, peeling and lifting may occur at an interface between the members constituting the insulation sheet 100. In addition, when the thickness of the graphite sheet is smaller than 15 μm, since the time for expressing the insulation effect is shortened, it may be difficult for the graphite sheet to express a sufficient insulation effect, and its use may be limited for insulation in applications where the heating element has a high temperature.

For example, a graphite sheet including one or more of pyrolytic graphite and graphitized polyimide may be used as the graphite sheet.

The pyrolytic graphite may refer to high-purity graphite having high thermal conductivity and electrical conductivity, may be used at a high temperature, and may be manufactured using a vapor deposition method, and thus may have a very well-developed microstructure.

Further, the graphitized polyimide may be formed by carbonizing and then heat-treating a polyimide film, and rolling the resulting polyimide film at a high temperature. Meanwhile, pores may be present between carbon stacks after carbonization or heat treatment. When the carbon stacks are aligned through rolling and the pores between the stacks are appropriately adjusted, not only heat dissipation performance may be improved through an increase in density, but also graphitized polyimide having reduced thermal conductivity in a vertical direction through the pores may be manufactured. Accordingly, the graphite sheet, which is the graphitized polyimide used in the present invention, may not contain pores or may appropriately contain pores between the carbon stacks.

Meanwhile, for example, the multilayer graphene sheet may be one formed through deposition, but the present invention is not limited thereto, and any known multi-multilayer graphene sheet may be employed without limitation.

Next, the first adhesive member 120 provided under the above-described insulation member 110 is for attaching the insulation sheet 100 to the attachment surface, and any known adhesive member may be used without limitation. For example, as shown in FIG. 1, the first adhesive member 120 may be formed of an adhesive layer.

Any adhesive layer commonly used in the art may be used as the adhesive layer without limitation, and the adhesive layer may be formed of an adhesive layer-forming composition including an adhesive component including, preferably one or more selected from the group consisting of an acrylic resin, a urethane resin, an epoxy resin, silicone rubber, acrylic rubber, a carboxyl nitrile elastomer, phenoxy, and a polyimide resin, and more preferably an acrylic resin. Further, the adhesive layer-forming composition may further include a curing agent when the adhesive component is a curable resin, and may further include an additive such as a curing accelerator or the like according to the purpose. Any curing agent commonly used in the art may be used as the curing agent without limitation, and the curing agent may include, preferably one or more selected from the group consisting of an epoxy-based curing agent, a diisocyanate-based curing agent, a secondary amine-based curing agent, a tertiary amine-based curing agent, a melamine-based curing agent, an isocyanate-based curing agent, and a phenol-based curing agent, and more preferably an epoxy-based curing agent.

Further, the adhesive layer may further include a known heat dissipation filler.

In addition, a thickness of the adhesive layer may be 7 to 55 μm, and preferably 10 to 50 μm. When the thickness of the adhesive layer is smaller than 7 μm, an interlayer adhesive strength may be reduced, and a case in which the thickness exceeds 55 μm is not preferable in terms of thinning, and considering the limited thickness of the insulation sheet 100, as the thickness of the insulation member 110 becomes relatively thin, heat dissipation and/or insulation characteristics may be lowered.

Meanwhile, as shown in FIG. 2, an insulation sheet 101 may include a first adhesive member 120′ including a first adhesive layer 123 and a second adhesive layer 121 on both surfaces of a base material 122.

The first adhesive layer 123 and the second adhesive layer 121 may be known adhesive layers, and since a description thereof is the same as the description of the adhesive layers in the above-described first adhesive member 120, a detailed description will be omitted. In this case, the materials, adhesive strength, and/or thicknesses of the first adhesive layer 123 and the second adhesive layer 121 may be the same or different.

Like the insulation sheet 101 shown in FIG. 2, the first adhesive member 120′ includes the base material 122, and in this case, compared to the first adhesive member 120 made of the adhesive layer shown in FIG. 1, the adhesion characteristics may be improved on the curved surface. The base material 122 may be a film formed of a known polymer resin such as a polyester-based resin, a polyamide-based resin, a polyolefin-based resin, or the like, a metal base material, and/or a nano fiber web. Preferably, the base material 122 may be a metal base material, and when a film formed of the polymer resin is used as the base material, wrinkles may be formed by heat transferred from a heating element, and accordingly, high temperature reliability may be lowered such as the possibility that lifting or peeling occurs at interfaces between the attachment surface and the first adhesive member 120′ and between first adhesive member 120′ and an insulation member 110. On the other hand, when the metal base material is used as the base material 122, high temperature reliability may be ensured, and there is an advantage in that the adhesive characteristics may be further improved even when curvature of the attaching surface is large.

Meanwhile, when the base material 122, which is a metal base material, is used, the insulation performance of the insulation sheet 101 may be further improved. In a description of an insulation chip on film package 1000 with reference to FIG. 10, when the metal base material is provided in the first adhesive member 120′, heat H of a display driving chip 500, which is a hot spot due to the thermal conductivity characteristics of the metal base may be primarily moved in a surface direction perpendicular to a thickness direction of the metal base material in the first adhesive member 120′ before being transferred to the insulation member 110. In this case, the size of a hot spot formed on the metal base material based on the insulation member 110 becomes larger than a size of the display driving chip 500, and thus heat which has reached the first surface of the insulation member 110 may be transferred quicker and in a greater amount in a surface direction perpendicular to a thickness direction of the insulation member 110, and relatively, an amount of heat transferred in the thickness direction from the first surface to the second surface may further decrease. Accordingly, since the heat transferred from the second surface of the insulation sheet 101 in a direction perpendicular to the second surface may be further reduced, a further improved insulation effect may be expressed.

Any metal base material commonly used in the art may be used as the metal base material without limitation, and preferably may be any one of a copper foil, an aluminum foil, a silver foil, a nickel foil, and a gold foil, or an alloy including two or more thereof or a metal film in which two or more thereof are mixed or two or more thereof are stacked as individual layers. Preferably, the metal base material may be a metal foil including one or more of a copper foil and an aluminum foil.

Meanwhile, a thickness of the metal base material may be 7 to 100 μm, preferably 7 to 75 μm, and more preferably 10 to 50 μm. When the thickness of the metal base material is smaller than 7 μm, a desired level of heat dissipation characteristics may not be expressed and a tearing phenomenon may occur, and when the thickness exceeds 75 μm, as thinning of the insulation sheet becomes difficult and flexibility is lowered, lifting and peeling between layers during bending may occur, and thus reliability may be lowered.

Further, the base material 122 may have a predetermined surface roughness by forming irregularities on the surface for improving adhesive characteristics with the above-described first adhesive layer 123 and/or second adhesive layer 121, but the present invention is not limited thereto.

In a description with reference to FIG. 5, a width and a length of the first adhesive member 120′ provided in an insulation sheet 103, in other words, a length and a width of the metal base material provided in the first adhesive member 120′ may be provided to be smaller than a length and a width of the insulation member 110. As described through FIG. 10, the metal base material implements a hot spot with an area larger than that of a hot spot, which is a heating element such as the display driving chip 500, and in this case, it may be sufficient to improve the insulation performance of the insulation member 110 when provided with this level of the area of the implemented hot spot, and accordingly, there is an advantage in that costs may be reduced.

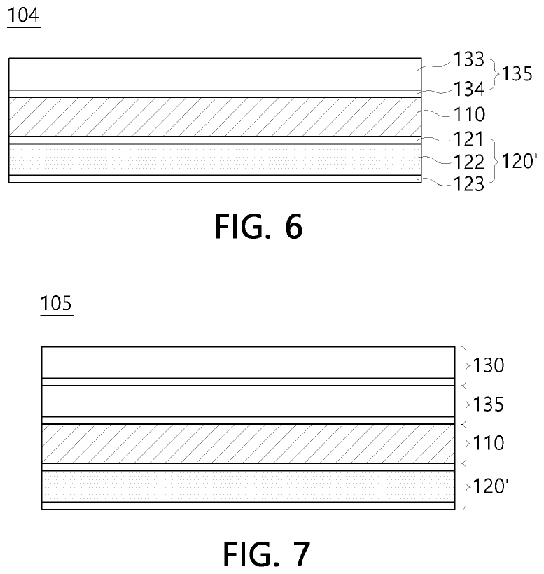

Next, the protective member 130 provided on the second surface of the above-described insulation member 110 will be described. The protective member 130 performs a function of physically and chemically protecting the insulation sheets 100 and 101. Any protective member 130 of a common sheet may be employed as the protective member 130 without limitation. For example, the protective member 130 may include a nonporous film, a nano fiber web, or a protective layer in which a nonporous film is stacked on a nano fiber web. The insulation sheets 100 and 101 shown in FIGS. 1 and 2 are cases of including nonporous films 131 as protective layers, an insulation sheet 104 in FIG. 6 is a case of including a nano fiber web 133 as a protective layer, and an insulation sheet 105 in FIG. 7 is a case of including a stack of the protective member 130 including a nonporous film as a protective layer and a protective member 135 including a nano fiber web as a protective layer. When the nano fiber web 133 is provided in the protective member 135, there is an advantage in that an insulation effect in a vertical direction through a plurality of pores provided in the nano fiber web 133 may be expressed together with a protection function. Meanwhile, as the pores of the nano fiber web provided in the protective member 135 including the nano fiber web are blocked from external air through the protective member 130 including the nonporous film, the insulation sheet 105 in FIG. 7 may have more excellent thermal performance than the insulation sheet 104 in FIG. 6.

The nonporous film 131 may be a film including one or more selected from the group consisting of polyimide, polyethylene terephthalate (PET), and polyethylene naphthalate (PEN). Further, the nano fiber web 133 may be a nano fiber web formed of a known material such as a urethane-based material, a fluorine-based material, polyacrylonitrile, or the like. In the nano fiber web 133, a diameter of a nano fiber may be 1 μm or less, but the present invention is not limited thereto.

The nonporous film 131 or the nano fiber web 133 may have a thickness of 10 to 30 μm, and preferably 13 to 25 μm. When the thickness is smaller than 10 μm, protection performance such as wear resistance or the like may be lowered, and when the thickness exceeds 30 μm, it may not be preferable in terms of of thinning, and flexibility may be lowered, and accordingly, peeling between layers may be caused.

Meanwhile, the protective members 130 and 135 may further include adhesive layers 132 and 134 to be fixed to the insulation member 110, respectively. Descriptions of the adhesive layers 132 and 134 respectively provided in the protective members 130 and 135 are the same as the description of the adhesive layer provided in the above-described first adhesive member 120 and thus detailed descriptions will be omitted, and materials of the adhesive layers 132 and 134 may be the same as or different from the adhesive layer provided in the first adhesive member 120.

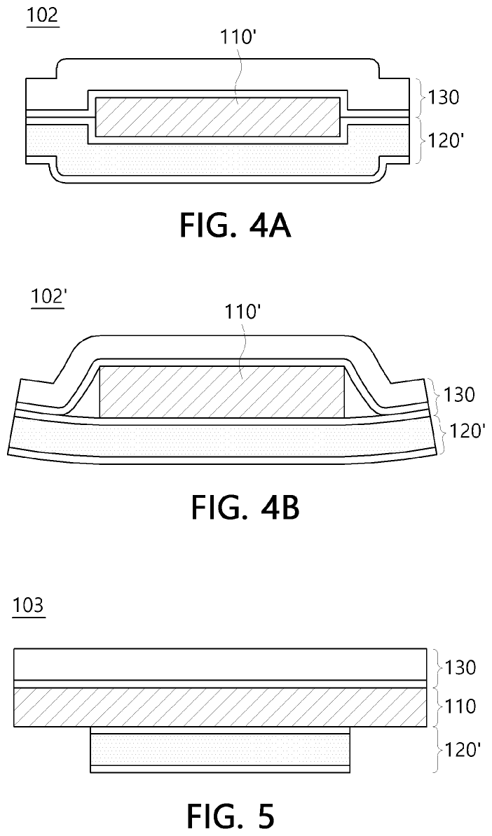

According to one embodiment of the present invention, in order to improve adhesive characteristics on an attachment surface having curvature, prevent peeling between layers in the insulation sheet, and prevent scattering of the dust which may occur due to damage to the insulation member 110 which may occur at any time, insulation sheets 102 and 102′ may have the structures shown in FIGS. 3, 4A, and 4B. Specifically, in the insulation sheet 102, a length and a width of each of the protective member 130 and the first adhesive member 120′ may be formed to be greater than a length and a width of the insulation member 110′ by a predetermined size (a) so that four side surfaces parallel to a thickness direction of the insulation member 110′ may be sealed through the protective member 130 and the first adhesive member 120′. For example, each of the protective member 130 and the first adhesive member 120′ may have a length and width of 27 mm and 13 mm, and the insulation member 110 may have a length and width of 26 mm and 12 mm. Meanwhile, the length and width of each of the insulation member 110′, the protective member 130, and the first adhesive member 120′ are not limited thereto, and may be appropriately changed in consideration of the size of a hot spot, desired insulation performance, and the like.

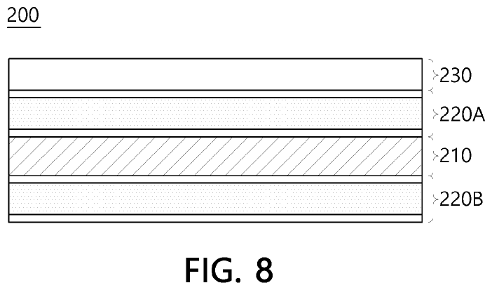

Further, in order to improve adhesive characteristics on an attachment surface having curvature, prevent peeling between layers in the insulation sheet after attachment, and ensure the visibility of inspection equipment, as shown in FIG. 8, an insulation sheet 200 may further include a second adhesive member 220A provided on an insulation member 210 in addition to a first adhesive member 220B provided under the insulation member 210. In addition, due to the second adhesive member 220A, in a protective member 230, a separate adhesive layer may be omitted, and a protective layer may be directly fixed on the insulation member 210 through the second adhesive member 220A.

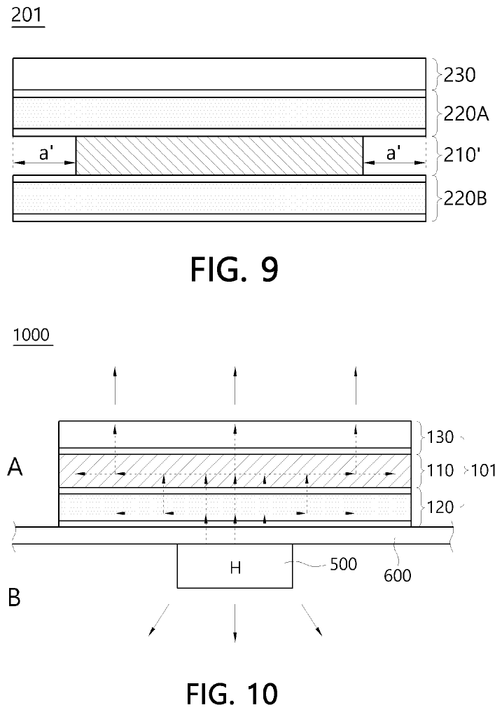

In addition, as shown in FIG. 9, in order to improve adhesive characteristics on an attachment surface having curvature, prevent peeling between layers in the insulation sheet, and prevent scattering of the dust which may occur due to damage to the insulation member which may occur at any time, as described above, in an insulation sheet 201 including the second adhesive member 220A and the first adhesive member 220B, a length and a width of each of the second adhesive member 220A, the protective member 230, and the first adhesive member 220B may be formed to be greater than a length and a width of an insulation member 201′ by a predetermined size (a) so that four side surfaces parallel to a thickness direction of the insulation member 201′ may be sealed through the second adhesive member 220A, the protective member 230, and the first adhesive member 220B. In this case, as shown in FIG. 9, the lengths and the widths of the second adhesive member 220A, the protective member 230, and the first adhesive member 220B may be the same or at least one thereof may be formed to be different.

Meanwhile, a release film for protecting exposed surfaces of the adhesive layers until attachment to the attachment surface may be further provided on the adhesive layers exposed in the first adhesive members 120, 120′, and 220B of the above-described insulation sheets 100, 101, 102, 103, 104, 200, and 201. Any known release film having release performance may be used as the release film without limitation, and the present invention is not specifically limited thereto.

Further, in the present invention, an insulation structure may be implemented by providing the above-described insulation sheets 100, 101, 102, 103, 104, 200, and 201 directly on various heating elements or on other surfaces of various base materials provided with heating elements on surfaces thereof. As an example of this, the insulation structure may be an insulation chip on film package in which an insulation sheet is provided on a chip on film employed in a display device. In this case, among the above-described insulation sheets, specifically, the insulation sheets shown in FIGS. 2, 3, 8, and 9 and in which the base materials 122 of the first adhesive members 120′ and 220B are metal base materials may be suitable as insulation sheets for a chip on film.

Specifically, in the chip on film, a display driving chip (a display driver IC, (DDI)) is mounted on one surface of a printed circuit film, and the insulation sheet 101, 102, 200, or 201 may be provided on an opposite surface of one surface of the printed circuit film, on which the display driving chip (DDI) is mounted, to block the transfer of heat generated from the display driving chip in a first direction perpendicular to the opposite surface.

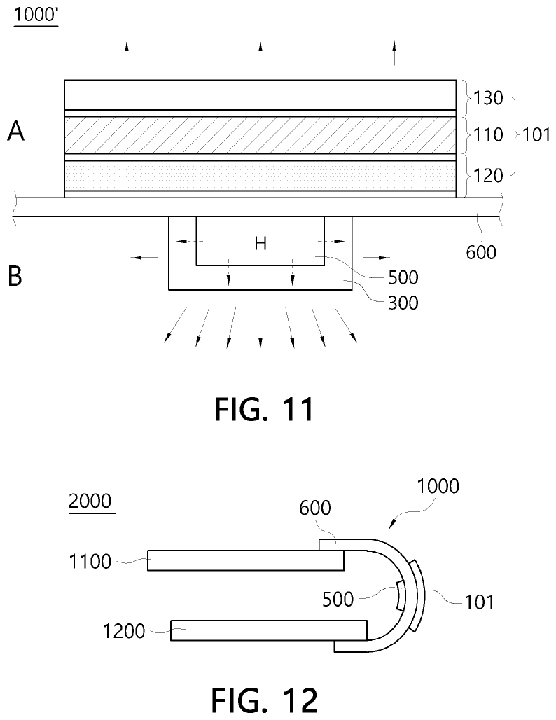

In a description with reference to FIGS. 10 and 11, an insulation chip on film package 1000 or 1000′ may include an printed circuit film 600, a display driving chip (DDI) 500 which is a hot spot provided on one surface of the printed circuit film 600, and an insulation sheet 101 provided on an opposite surface of one surface of the printed circuit film 600 provided with the display driving chip 500 for delaying or preventing the movement of heat H generated from the display driving chip 500 in a first direction A perpendicular to the opposite surface of the one surface of the printed circuit film 600.

In this case, it is preferable that an insulation sheet 101 having a larger area than the display driving chip 500, which is a hot spot. is applied, and accordingly, as described above, it is possible to implement a hot spot, which is wider than a size of the display driving chip 500 in a surface direction, through the metal base material in the first adhesive member 120′, and the widened hot spot is implemented as a wider hot spot in the insulation member 110 in the surface direction perpendicular to the thickness direction of the insulation member 110, and thus it is possible to minimize heat transfer from the insulation sheet 101 toward a side perpendicular to a thickness direction of the insulation sheet 101 compared to a case applied with a size smaller than or equal to that of the display driving chip 500, which is a hot spot. Meanwhile, the insulation sheet 101 shows a heat dissipation effect for the display driving chip 500 by receiving the heat of the display driving chip 500 which is a hot spot provided at one side B of the printed circuit film 600, and accordingly, it is possible to minimize or prevent the performance of the display driving chip 500 from being lowered or deteriorating. Preferably, the area of the insulation sheet 101 may be provided to be three to five times larger than the area of the display driving chip 500, and accordingly, this may be advantageous for expressing more improved insulation performance.

Further, in order to achieve more improved insulation performance and heat dissipation performance, as shown in FIG. 11, a heat dissipation member 300 may be further provided on the exposed surface of the display driving chip 500. In this case, as the improved heat dissipation effect is expressed in the direction toward the one side B of the printed circuit film 600, the other side A of the printed circuit film 600 may exhibit a more improved insulation effect. Since any known heat dissipation member may be used as the heat dissipation member 300 without limitation in material, structure, and the like, detailed descriptions thereof will be omitted in the present invention.

Meanwhile, the display driving chip 500 may be an element mounted on a common display chip on film, and the present invention is not specifically limited thereto.

Further, the printed circuit film 600 may be a printed circuit film used in a common display chip-on-film, and may be, for example, a printed circuit film in which lines are printed on a polyimide film.

In addition, in the present invention, a display module in which a display panel unit and a circuit board disposed adjacent to the display panel unit are electrically connected may be implemented through the above-described insulation chip on film package 1000 or 1000′. In a description with reference to FIG. 12, a display module 2000 may be implemented by including a display panel unit 1100 including a glass substrate and a panel provided on the glass substrate, a circuit board 1200 disposed adjacent to be spaced apart from the display panel unit 1100, and the insulation chip on film package 1000 of which one end is electrically connected to the display panel unit 1100, and the other end is electrically connected to the circuit board 1200. In this case, as shown in FIG. 12, the display module 2000 may minimize or block the transfer of heat from the insulation sheet 101 toward a side perpendicular to the thickness direction of the insulation sheet 101 in consideration of a positional relationship between the display driving chip 500 and the insulation sheet 101 in the insulation chip on film package 1000.

Meanwhile, a distance between the display panel unit 1100 and the circuit board 1200 may be decreased for miniaturization or slimming of the display device, and accordingly, the printed circuit film 600 in the insulation chip on film package 1000 may be bent more and thus curvature may increase, and even when the curvature of the printed circuit film 600 increases more, and the insulation sheet 101 is attached to a point where the curvature is greatest, the insulation sheet 101 may be stably attached to a curved surface through the improved material, structure, and the like of the above-described insulation sheet 101 according to the present invention.

Further, the above-described display module 2000 may be assembled with a housing surrounding at least a portion of the display module 2000 to be implemented as a display device.

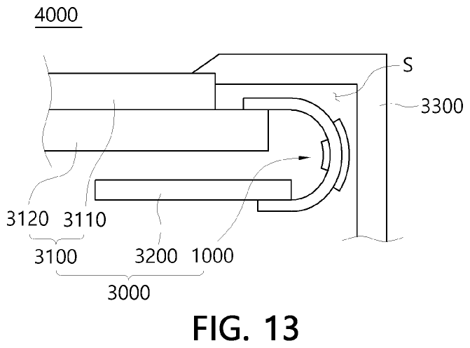

In a description with reference to FIGS. 13 to 15, for example, a display device 4000 or 4000′ may be implemented by assembling a display module 3000 including a display panel unit 3100, a circuit board 3200 disposed adjacent to be spaced apart from an opposite surface of a surface on which an image is displayed in the display panel unit 3100, and an insulation chip on film package 1000 which electrically connects the display panel unit 3100 and the circuit board 3200, and a housing 3300 surrounding an edge of the display module 3000 and the opposite surface of the surface on which the image is displayed.

Any known panel unit in the art may be employed as the display panel unit 3100 without limitation. For example, the display panel unit 3100 may include a glass substrate 3120 and a panel 3110 on the glass substrate 3120.

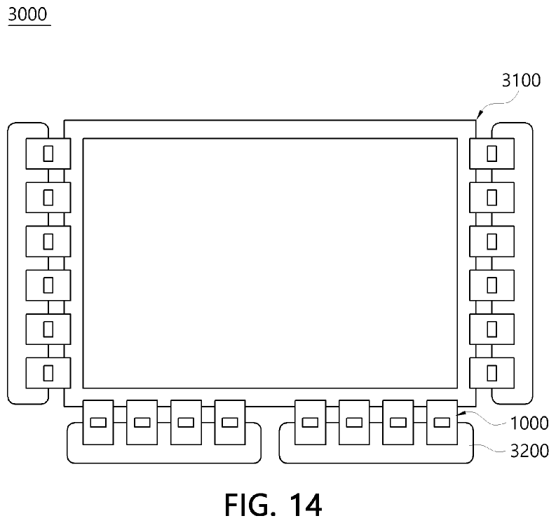

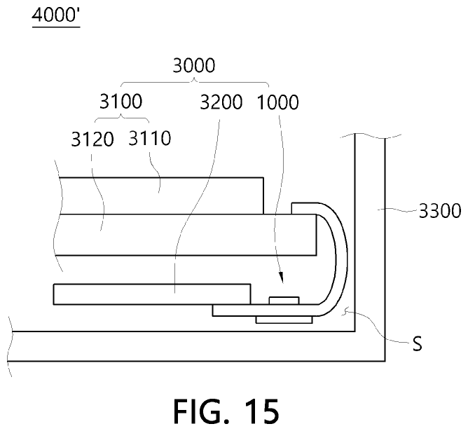

Meanwhile, in the display module 3000 shown in FIG. 14, insulation chip on film packages 1000 in a form in which the insulation sheet is attached to a chip on film (COF) are disposed at three edges of the display panel unit 3100, and in addition, a plurality of insulation chip on film packages 1000 are employed at each edge. The number of chip on films connected to a display panel in a conventional display is one or two to four, but as a recent display has higher resolution, as shown in FIG. 14, each of the three edges of the display panel unit 3100 is provided with several chip on films, and this is more inevitable in the case of high-resolution and large-area displays such as 4K and 8K. However, when tens of chip on films (COFs) are provided in a display without an insulation sheet, an amount of heat generated from all DDI chips when the display is driven is very large, and accordingly, as shown in FIGS. 14 and 15, as the heat generated from the DDI chips is transferred to the housing 3300, a temperature of a surface of the housing 3300 rises to a ridiculous level in a conventional display housing, and thus there is a risk of fire or burns. Further, since the slimming trend of electronic devices is not excluded in the case of displays, a distance between side ends or opposite surface of the surface on which the image is displayed of the display panel unit 3100 and the housing 3300 is very narrow, and thus the temperature increase problem of the housing 3300 worsens. However, as shown in FIGS. 14 and 15, the insulation chip on film package 1000 may minimize heat transfer from an opposite surface facing one surface of the insulation sheet which comes into contact with the printed circuit film to the inner side of the housing 3300 perpendicular to the opposite surface, and thus may minimize a rise in temperature of the housing 3300.

Further, the heat transfer to the housing 3300 may be further prevented by forming an air layer in a space S between the inner side of the housing 3300 and the insulation chip on film package 1000. Meanwhile, the space S may be filled with a separate insulation material such as urethane foam or the like, but considering that a volume of the space S decreases due to the electronic device becoming slim, the air layer has an advantage in that transfer of a huge amount of heat generated from the chip on film to the housing 3300 may be minimized compared to the separate insulation material.

Meanwhile, as shown in FIGS. 14 and 15, a position of the display driving chip in the insulation chip on film package 1000 may be changed according to a structure of a display device to be designed, and it should be noted that a position of the insulation sheet may also be changed according to the position of the display driving chip to be changed.

Although embodiments of the present invention have been described above, the spirit of the present invention is not limited to the embodiments shown in the description, and although those skilled in the art may provide other embodiments through the addition, change, or removal of the components within the scope of the same spirit of the present invention, these are also included in the scope of the spirit of the present invention.

1. An insulation sheet for a chip on film (COF) provided on an opposite surface of one surface of a printed circuit film, on which a display driving chip (a display driver IC, (DDI)) is mounted, to block the transfer of heat generated from the display driving chip in a first direction perpendicular to the opposite surface, the insulation sheet comprising:
an insulation member formed of a graphite sheet including a first surface and a second surface facing each other and having a surface direction perpendicular to a thickness direction, and having functions of receiving heat toward the first surface adjacent to the display driving chip to lower a heating temperature of the display driving chip, and moving the received heat more in the surface direction than in the thickness direction to minimize heat transfer in the first direction from the second surface;
a first adhesive member including a metal base material for forming a hot spot larger than an area of the display driving chip and having high temperature reliability, a first adhesive layer attached to the opposite surface of the printed circuit film at a position corresponding to the display driving chip, and a second adhesive layer attached to the first surface of the insulation member; and
a protective member provided on the second surface of the insulation member.

2. The insulation sheet of claim 1, wherein a length and a width of each of the protective member and the first adhesive member are formed to be greater than a length and a width of the insulation member so that four side surfaces parallel to the thickness direction of the insulation member are sealed through the protective member and the first adhesive member.

3. The insulation sheet of claim 1, wherein:
the protective member is a protective film including one or more selected from the group consisting of polyimide, polyethylene terephthalate (PET), and polyethylene naphthalate (PEN); and
the insulation sheet further comprises an adhesive layer to be fixed to the insulation member on one surface of the protective film.

4. The insulation sheet of claim 1, wherein the graphite sheet includes one or more sheets of an artificial graphite sheet and a multilayer graphene sheet.

5. The insulation sheet of claim 1, wherein a thickness of the graphite sheet is 15 to 100 μm.

6. The insulation sheet of claim 1, wherein the metal base material is a metal foil including one or more of a copper foil and an aluminum foil.

7. The insulation sheet of claim 1, wherein:
a thickness of the metal base material is 7 to 75 μm; and
thicknesses of the first adhesive layer and the second adhesive layer are each independently 7 to 55 μm.

8. The insulation sheet of claim 1, wherein a length and a width of the metal base material are provided to be greater than a length and a width of the display driving chip, and smaller than a length and a width of the graphite sheet.

9. The insulation sheet of claim 1, wherein a release film is further provided on the first adhesive layer of the first adhesive member.

10. The insulation sheet of claim 1, further comprising a second adhesive member between the protective member and the insulation member,
wherein the second adhesive member includes a third adhesive layer attached to the protective member, a fourth adhesive layer attached to the insulation member, and a metal base material interposed between the third adhesive layer and the fourth adhesive layer.

11. The insulation sheet of claim 10, wherein a length and a width of each of the protective member, the first adhesive member, and the second adhesive member are formed to be greater than a length and a width of the insulation member so that four side surfaces parallel to the thickness direction of the insulation member are sealed through the protective member, the first adhesive member, and the second adhesive member.

12. An insulation chip on film (COF) package comprising:
a printed circuit film;
a display driving chip (DDI) disposed on one surface of the printed circuit film; and
the insulation sheet for a chip on film (COF) according to claim 1 disposed on an opposite surface of the printed circuit film at a position corresponding to the display driving chip.

13. The package of claim 12, wherein an area of the insulation sheet for a chip on film (COF) is provided to be three to five times larger than an area of the display driving chip.

14. (canceled)

15. A display device comprising:
a display module including a display panel unit, a circuit board disposed to be spaced apart from the display panel unit, and the insulation chip on film package according to claim 12 of which one end is electrically connected to the display panel unit, and the other end is electrically connected to the circuit board; and
a housing surrounding at least a portion of the display module.

16. The display device of claim 15, wherein:
the insulation chip is disposed in a space between an inner side surface of the housing and the display panel unit;
an insulation sheet for a chip on film provided in the insulation chip on film package is disposed to face the inner side surface of the housing; and
an air layer is formed between the insulation sheet and the inner side surface of the housing to prevent heat transfer from an exposed surface of the insulation sheet for a chip on film toward the inner side surface of the housing perpendicular to the exposed surface of the insulation sheet for a chip on film.

17-25. (canceled)
